(19) United States
(12) Patent Application Publication
(10) Pub. No.: US 2011/0263074 A1
(43) Pub. Date: Oct. 27, 2011

(54) APPARATUS AND METHODS FOR REDUCING LIGHT INDUCED DAMAGE IN THIN FILM SOLAR CELLS

(75) Inventors: Amir Al-Bayati, San Jose, CA (US); Yong K. Chae, San Ramon, CA (US); Shuran Sheng, Cupertino, CA (US); Bhaskar Kumar, Santa Clara, CA (US); Eran Valfer, Dresden (DE)

(73) Assignee: Applied Materials, Inc., Santa Clara, CA (US)

(21) Appl. No.: 12/765,458

(22) Filed: Apr. 22, 2010

(51) Int. Cl. H01L 31/18

(52) U.S. Cl. 438/96; 118/663; 257/E31.047; 257/E31.001

(57) ABSTRACT

Apparatus and methods for forming a silicon-containing i-layer on a substrate for a thin film photovoltaic cell are disclosed. The apparatus includes a chamber body defining a processing region containing the substrate, a hydrogen source and a silane source coupled to a plasma generation region, an RF power source that applies power at a power level in the plasma generation region to generate a plasma and deposit the silicon-containing i-layer at a selected deposition rate to a selected thickness and a controller. The controller controls the power level and the deposition rate of the i-layer on the substrate such that the thin film solar cell exhibits light induced damage that conforms to a linear fit of the product of the RF power, the deposition rate and the selected thickness of the i-layer. In accordance with further aspects of the present invention, the controller controls the RF power and the deposition rate so that a product (x) of the RF power in watts, the deposition rate of the i-layer in nm per min and the thickness of the i-layer in nm is less than a predetermined number y and satisfies the equation y=5E11*x+3.3749 plus or minus a margin.

### BACKGROUND

The present invention relates to apparatus and methods for forming a silicon-containing i-layer on a substrate to reduce light induced damage in thin film solar cells.

Light induced damage is experienced with manufacturing both single and tandem junction solar cells. The light induced damage in the amorphous Si absorber i-layer reduces the initial efficiency of both single and tandem junction solar cells, typically by more than 20%. The light induced damage experienced is typically in the 12% to 25% range.

Prior to the present invention, it has been difficult if not impossible to reduce the light induced damage while manufacturing a silicon-containing i-layer on a substrate for a thin film photovoltaic cell to below 12%. Accordingly, in view of these drawbacks, improved apparatus and methods for reducing light induced damage when forming a silicon-containing i-layer on a substrate are needed

### SUMMARY

In accordance with one aspect of the present invention, an apparatus for forming a silicon-containing i-layer on a substrate for a thin film photovoltaic cell is provided. The apparatus includes a chamber body defining a processing region containing the substrate, a hydrogen source and a silane source coupled to a plasma generation region, an RF power source that applies power at a power level in the plasma generation region to generate a plasma and deposit the silicon-containing i-layer at a selected deposition rate to a selected thickness, and a controller that controls the power level and the deposition rate of the i-layer on the substrate such that the thin film solar cell exhibits light induced damage that conforms to a linear fit of the product of the RF power, the deposition rate and the selected thickness of the i-layer.

In accordance with a further aspect of the present invention, the controller controls the RF power and the deposition rate so that a product (x) of the RF power in watts, the deposition rate of the i-layer in nm per min and the thickness of the i-layer in nm is less than a predetermined number y and satisfies the equation y=5E11*x+3.3749 plus or minus a margin which is less than 10%. Tighter margins can be used. For example, a margin of less than 5% can be used.

The variable y corresponds to a desired light induced damage in the substrate. In accordance with one aspect of the invention, y is 12 or less. In accordance with a further aspect of the present invention y is 10 or less. In accordance with another aspect of the present invention, y is selected to be 8 or less.

In accordance with other aspects of the present invention, the deposition temperature is greater than or equal to 230° C. A deposition temperature of greater than approximately 250° C. can also be used.

In accordance with other aspects of the present invention, a ratio of H₂/SiH₄ is 6 or less. A ratio of H₂/SiH₄ of 4 or less can be used.

In accordance with further aspects of the present invention, a flow rate of SiH₄ is less than 2250 sccm.

The present invention also contemplates a method of forming a thin film solar cell including an i-layer comprising in a processing chamber. The method includes the steps of selecting a predetermined thickness of the i-layer to be formed on the substrate, flowing silane and hydrogen gas into a plasma generation region of the chamber, applying RF power at a selected power level to the plasma generation region to generate a plasma, depositing the amorphous i-layer to the predetermined thickness at a deposition rate and controlling the deposition rate and RF power level such that the thin film solar cell exhibits light induced damage that conforms to a linear fit of the product of RF power, the deposition rate and the thickness of the i-layer. The method also includes controlling the RF power and the deposition rate so that a product (x) of the RF power in watts, the deposition rate of the i-layer in nm per min and the thickness of the i-layer in nm is less than a predetermined number y and satisfies the equation y=5E11*x+3.3749 plus or minus a margin which is less than 10%. As described above, the margin can be less than 5%.

As before, y can be selected to be 12 or less, 10 or less or 8 or less.

In accordance with other aspects of the present invention, an apparatus for forming a silicon-containing i-layer on a substrate for a thin film photovoltaic cell is provided. The apparatus includes a chamber body defining a processing region containing the substrate, a hydrogen source and a silane source coupled to a plasma generation region, an RF power source that applies power at a power level in the plasma generation region to generate a plasma and a controller that controls the power level and a deposition rate of the i-layer on the substrate such that a product (x) of the power level in watts, the deposition rate of the i-layer in nm per min and the thickness of the i-layer in nm is less than a predetermined number y and satisfies the equation y=5E11*x+3.3749 plus or minus a margin which is less than 10% so that the silicon-containing i-layer is deposited on the substrate.

### DRAWINGS

FIG. 1 is a simplified schematic diagram of a single junction amorphous silicon solar cell that may be formed, in part, using methods and apparatus according to embodiments of the present invention.

FIG. 2 is a schematic diagram of another embodiment of a multi-junction solar cell that may be formed, in part, using methods and apparatus according to embodiments of the present invention;

FIG. 3 is a schematic, cross-sectional view of a processing chamber for deposition amorphous and microcrystalline films according to one or more embodiments of the invention;

FIG. 4 illustrates a relationship between the percentage of light induced damage in a substrate deposited onto a wafer to the product of deposition rate and substrate thickness used during processing of the wafer.

FIG. 5 illustrates a relationship between the percentage of light induced damage in a substrate deposited onto a wafer to the RF power used during the processing of the wafer.

FIG. 6 illustrates a relationship between the percentage of light induced damage in a substrate deposited onto a wafer to the deposition rate achieved during the processing of the wafer.

FIG. 7 illustrates a relationship between the percentage of light induced damage in a substrate deposited onto a wafer to substrate thickness of the substrate deposited onto a wafer.

FIG. 8 illustrates a relationship between the percentage of light induced damage in a substrate deposited onto a wafer to a product of three parameters used during the processing of the wafer in accordance with an aspect of the present invention.

FIGS. 9 and 10 illustrate processing steps used in accordance with aspects of the present invention.

### DESCRIPTION

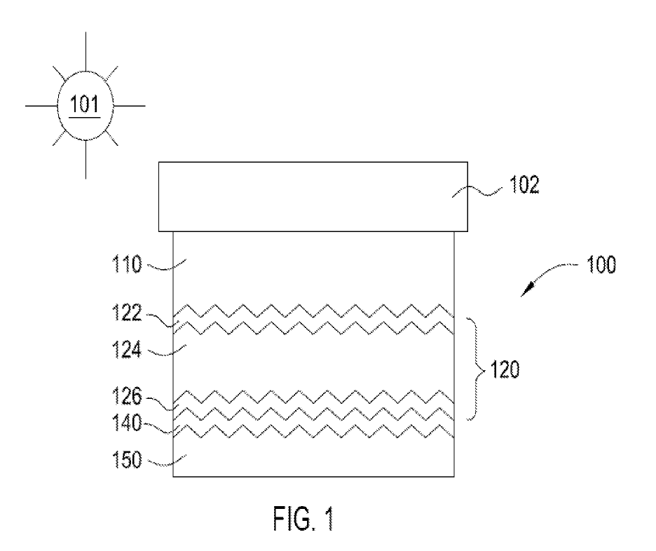

FIG. 1 is a simplified schematic diagram of a single junction amorphous silicon solar cell 100 that may be formed, in part, using methods and apparatus according to embodiments of the present invention. The single junction solar cell 100 is oriented toward a light source or solar radiation 101. The solar cell 100 generally comprises a substrate 102, such as a glass substrate, polymer substrate, metal substrate, or other suitable substrate, with thin films formed thereover. In one embodiment, the substrate 102 is a glass substrate that is about 2200 mm×2600 mm×3 mm in size. The solar cell 100 further comprises a first transparent conducting oxide (TCO) layer 110 (e.g., zinc oxide (ZnO), tin oxide (SnO)) formed over the substrate 102, a first p-i-n junction 120 formed over the first TCO layer 110, a second TCO layer 140 formed over the first p-i-n junction 120, and a back contact layer 150 formed over the second TCO layer 140.

In one configuration, the first p-i-n junction 120 may comprise a p-type amorphous silicon layer 122, an intrinsic type amorphous silicon layer 124 formed over the p-type amorphous silicon layer 122, and an n-type amorphous silicon layer 126 formed over the intrinsic type amorphous silicon layer 124. In one example, the p-type amorphous silicon layer 122 may be formed to a thickness between about 60 Å and about 300 Å, the intrinsic type amorphous silicon layer 124 may be formed to a thickness between about 1,500 Å and about 3,500 Å, and the n-type amorphous silicon layer 126 may be formed to a thickness between about 100 Å and about 500 Å. The back contact layer 150 may include, but is not limited to, aluminum (Al), silver (Ag), titanium (Ti), chromium (Cr), gold (Au), copper (Cu), platinum (Pt), alloys thereof, or combinations thereof.

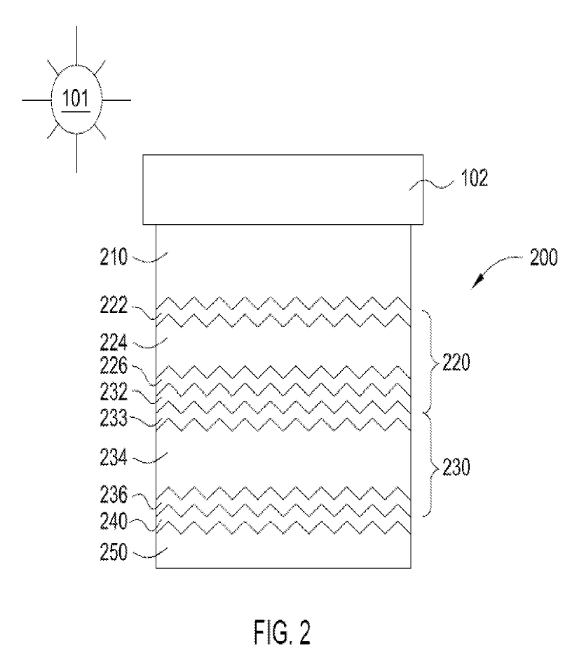

FIG. 2 is a schematic diagram of an embodiment of a solar cell 200, which is a multi-junction solar cell that is oriented toward the light or solar radiation 101. The solar cell 200 comprises a substrate 102, such as a glass substrate, polymer substrate, metal substrate, or other suitable substrate, with thin films formed thereover. The solar cell 200 may further comprise a first transparent conducting oxide (TCO) layer 210 formed over the substrate 102, a first p-i-n junction 220 formed over the first TCO layer 210, a second p-i-n junction 230 formed over the first p-i-n junction 220, a second TCO layer 240 formed over the second p-i-n junction 230, and a back contact layer 250 formed over the second TCO layer 240.

The first p-i-n junction 220 may comprise a p-type amorphous silicon layer 222, an intrinsic type amorphous silicon layer 224 formed over the p-type amorphous silicon layer 222, and an n-type microcrystalline silicon layer 226 formed over the intrinsic type amorphous silicon layer 224. In one example, the p-type amorphous silicon layer 222 may be formed to a thickness between about 60 Å and about 300 Å, the intrinsic type amorphous silicon layer 224 may be formed to a thickness between about 1,500 Å and about 3,500 Å, and the n-type microcrystalline semiconductor layer 226 may be formed to a thickness between about 100 Å and about 400 Å.

The second p-i-n junction 230 may comprise a p-type microcrystalline silicon layer 232, an intrinsic type microcrystalline silicon layer 234 formed over the p-type microcrystalline silicon layer 232, and an n-type amorphous silicon layer 236 formed over the intrinsic type microcrystalline silicon layer 234. In one embodiment, prior to deposition of the intrinsic type microcrystalline silicon layer 234, an intrinsic microcrystalline silicon seed layer 233 may be formed over the p-type microcrystalline silicon layer 232. In one example, the p-type microcrystalline silicon layer 232 may be formed to a thickness between about 100 Å and about 400 Å, the intrinsic type microcrystalline silicon layer 234 may be formed to a thickness between about 10,000 Å and about 30,000 Å, and the n-type amorphous silicon layer 236 may be formed to a thickness between about 100 Å and about 500 Å. In one embodiment, the intrinsic microcrystalline silicon seed layer 233 may be formed to a thickness between about 50 Å and about 500 Å. The back contact layer 250 may include, but is not limited to, aluminum (Al), silver (Ag), titanium (Ti), chromium (Cr), gold (Au), copper (Cu), platinum (Pt), alloys thereof, or combinations thereof.

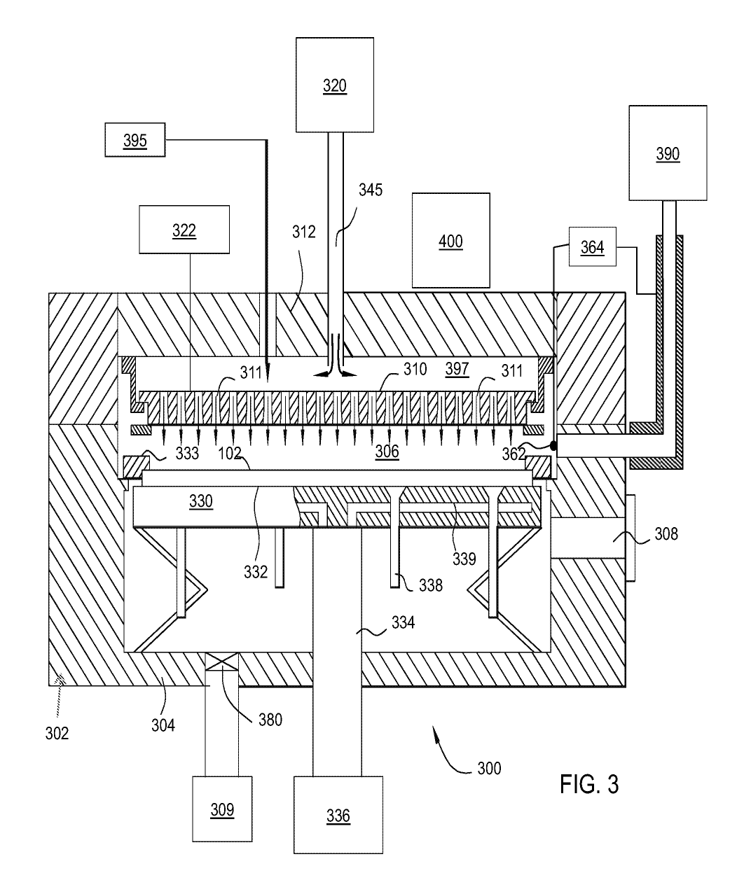

Current methods of depositing the various amorphous and microcrystalline silicon films to form the solar cell 100 or 200 include introducing a mixture of hydrogen-based gas, such as hydrogen gas (H₂), and silicon-based gas, such as silane (SiH₄), into a processing region of a plasma enhanced chemical vapor deposition (PECVD) processing chamber, exciting the gas mixture into a plasma, and depositing the desired film on the substrate 102. FIG. 3 is a schematic, cross-sectional view of a processing chamber 300 for depositing amorphous and microcrystalline films according to one embodiment of the present invention. In one embodiment, the chamber 300 includes walls 302, a bottom 304, a showerhead 310, and a substrate support 330, which cumulatively define a processing region 306. The processing region 306 is accessed through a valve 308, such that a substrate 102 may be transferred into and out of the chamber 300. The substrate support 330 includes a substrate receiving surface 332 for supporting the substrate 102 and stem 334 coupled to a lift system 336 configured to raise and lower the substrate support 330. A shadow frame 333 may be optionally placed over a periphery of the substrate 102. Lift pins 338 are moveably disposed through the substrate support 330 to move the substrate 102 to and from the substrate receiving surface 332. The substrate support 330 may also include heating and/or cooling elements 339 to maintain the substrate support 330 at a desired temperature.

A hydrogen-containing gas source 390 is fluidly coupled to the processing region 306 of the processing chamber 300 through a gas conduit. The hydrogen-containing gas source 390 of specific embodiments can be isolated from a silicon-containing gas source 320 to prevent mixing of the hydrogen-containing gas and the silicon-containing gas outside of the processing region 306 of the processing chamber 300.

In the embodiment of FIG. 3, the gas conduit from source 390 is positioned to introduce the hydrogen-containing gas to the processing region 306 through the chamber wall 302. In other embodiments, the gas conduit 345 is positioned to introduce the hydrogen-containing gas to the processing region 306 via alternate routes including, but not limited to, through the showerhead 310.

In some embodiments, an RF power source 322 is coupled to the backing plate 312 and/or to the showerhead 310 to provide an RF power to the showerhead 310 so that an electric field is created between the showerhead 310 and the substrate support 330 or chamber walls 302. Thus, the hydrogen-containing gas in the processing region 306 is energized to generate hydrogen radicals as a capacitively coupled plasma for depositing a film on the substrate 102. A vacuum pump 309 is also coupled to the processing chamber 300 through a throttle valve 380 to control the processing region 306 at a desired pressure. In some embodiments, as described here, the hydrogen radicals are generated after the heated hydrogen-containing gas is introduced into the processing region 306 of the processing chamber 300. In alternate embodiments, as described later, the hydrogen radicals can be generated before the heated hydrogen-containing gas is introduced into the processing region 306 of the processing chamber 300. This can be done with a remote plasma source.

In detailed embodiments, the processing chamber 300 comprises a temperature feedback circuit 364 including at least one temperature probe 362 coupled to an optional heater jacket 351 for monitoring the temperature of the hydrogen-containing gas entering the processing chamber 300. The feedback circuit 364 is configured to measure the temperature of the hydrogen-containing gas and adjust the heater jacket 351, and therefore the hydrogen-containing gas, based on the measured temperature to control the hydrogen-containing gas temperature. The at least one temperature probe 362 can be placed in any suitable location. In FIG. 3, the temperature probe 362 is placed on the inside of the chamber 300 at the end of the gas conduit 345. This allows the temperature feedback circuit 364 to adjust the temperature of the heater jacket 351 so that the gas entering the chamber 300 is at a specified temperature. The location of the temperature probe 362 can be moved without deviating from the scope and spirit of the invention.

A gas source 320 is configured to supply a processing gas, such as a silicon-containing gas, through a gas conduit 345. For deposition of the silicon films, a silicon-containing gas is generally provided by the gas source 320. In detailed embodiments, the silicon-containing gas is introduced into the processing chamber 300 as an unheated gas. As used in this specification and the appended claims, the term “unheated” means that the gas is at the temperature of the surrounding environment. This environment can be the room where the gas is stored, or the tubes that the gas pass through or the body of the processing chamber 300. In specific embodiments, the silicon-containing gas has a temperature lower than the ambient environment. Suitable silicon-containing gases include, but are not limited to silane (SiH₄), disilane (Si₂H₆), silicon tetrafluoride (SiF₄), silicon tetrachloride (SiCl₄), dichlorosilane (SiH₂Cl₂), and combinations thereof. In specific embodiments, the silicon-containing gas is silane. In some embodiments, the processing chamber 300 also includes a cleaning gas remote plasma source 395 that is fluidly coupled to a gas plenum 397, located behind the showerhead 310, and further coupled to the processing region 306 through the gas passages 311 formed in the showerhead 310.

A controller 400 is connected to the processing chamber 300 to control various aspects of the manufacturing process, including the deposition of the intrinsic layer (i-layer). The controller 400 controls the RF power level applied to the processing chamber 306. It also controls the volume of each of the gases introduced into the chamber 306 and the flow rate of the gases. The gases can be introduced and controlled individually or in combination with each other. By controlling these parameters, the controller 400 can also control the deposition rate of the i-layer onto the substrate 120. The controller 400 can be any type of processor. For example, it can include a personal computer, a specially designed processor circuit or a microprocessor/microcontroller based specially designed circuit.

As previously mentioned, the formation of the i-layer in the manufactured devices is susceptible to light induced damage. This light induced damage in the i-layer creates substantial efficiency problems. In accordance with various aspects of the invention, various processing parameters were investigated to determine an optimal way to control the controller 400 to reduce light induced damage.

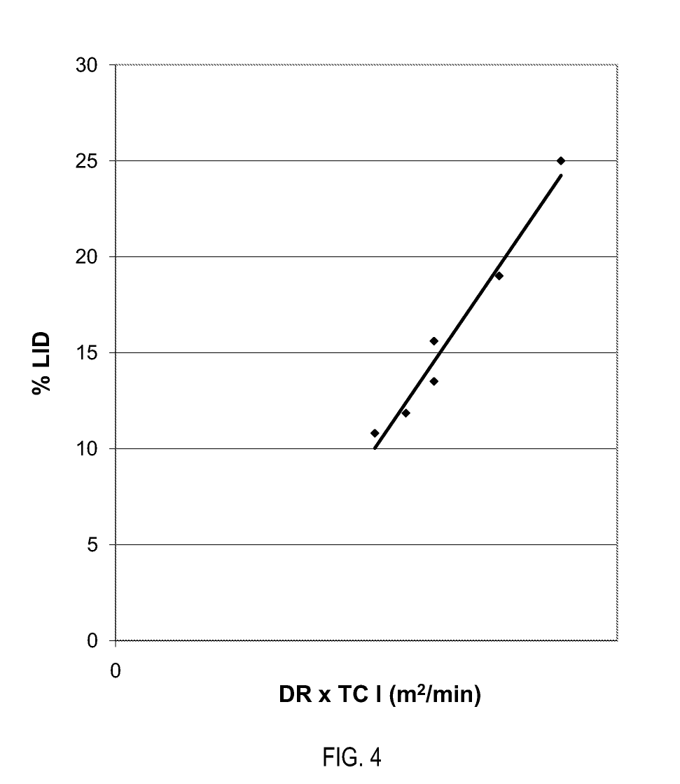

FIG. 4 illustrates a relationship between the percentage of light induced damage (% LID) in a substrate deposited onto a wafer to the product of deposition rate and substrate thickness used during processing of the wafer. The relationship is shown for light induced damage greater than approximately 12 percent. The operating points obtained do not yield a good linear fit. Consequently, in accordance with one aspect of the present invention, it is postulated that focusing on the product of deposition rate and substrate thickness during processing will not yield improved light induced damage results.

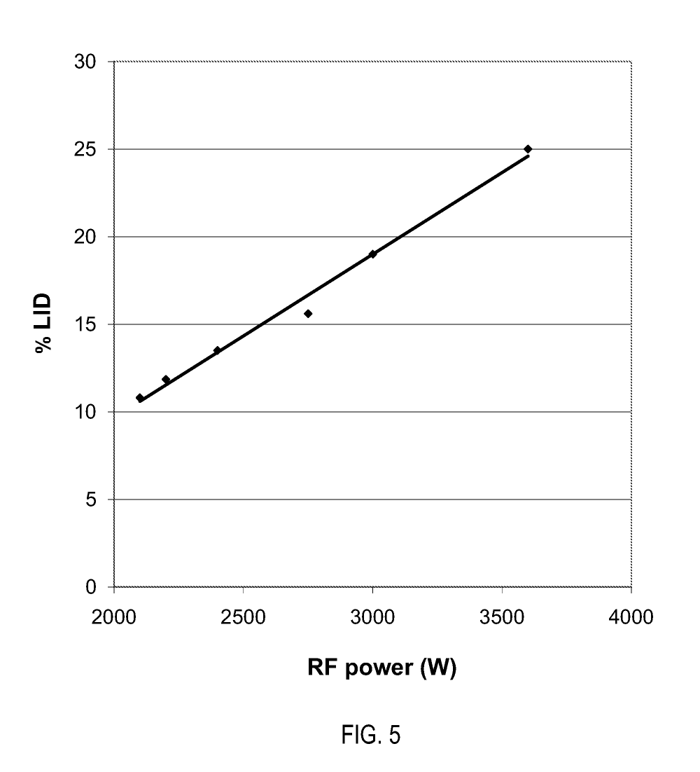

FIG. 5 illustrates a relationship between the percentage of light induced damage (% LID) in a substrate deposited onto a wafer to the RF power used during the processing of the wafer. The operating points obtained are close to yielding a predictable linear relationship, but are not considered to be an ideal linear fit. Consequently, it is believed that focusing on the RF power during processing is a potential method to achieve improved light induced damage results, but perhaps not the optimal method.

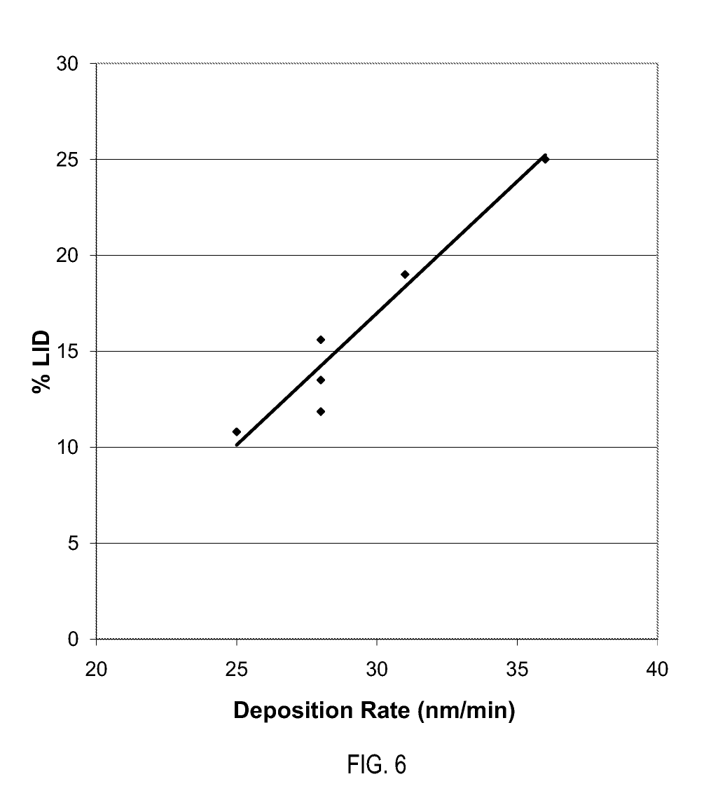

FIG. 6 illustrates a relationship between the percentage of light induced damage (% LID) in a substrate deposited onto a wafer to the deposition rate achieved during the processing of the wafer. In this case, the operating points obtained do not yield a good linear fit. Consequently, it is believed that focusing on the deposition rate solely will not yield improved light induced damage results.

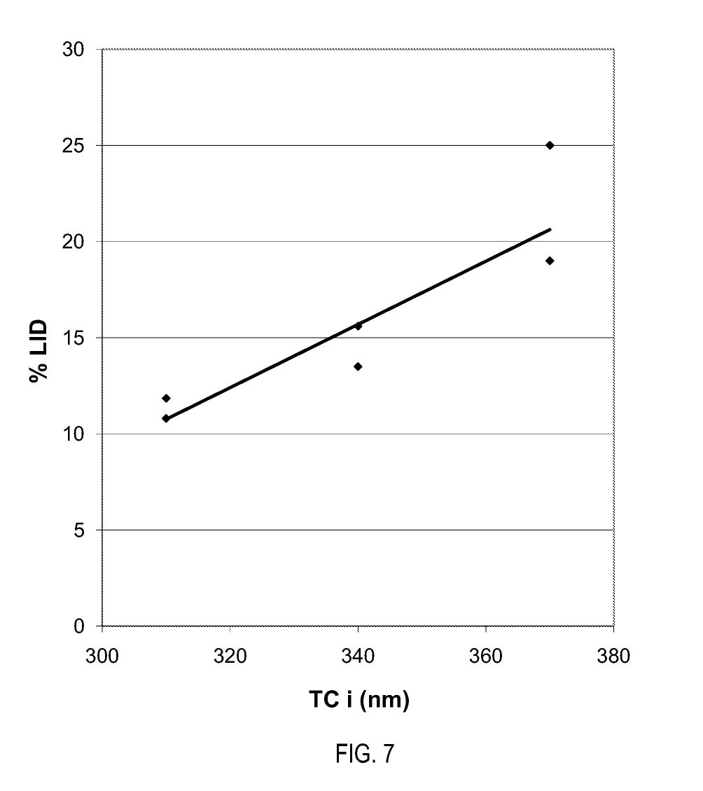

FIG. 7 illustrates a relationship between the percentage of light induced damage (% LID) in a substrate deposited onto a wafer to substrate thickness of the substrate deposited onto a wafer. In this case, once again, the operating points obtained do not yield a good linear fit. Consequently, it is believed that focusing on the product of deposition rate and substrate thickness during processing will not yield improved light induced damage results.

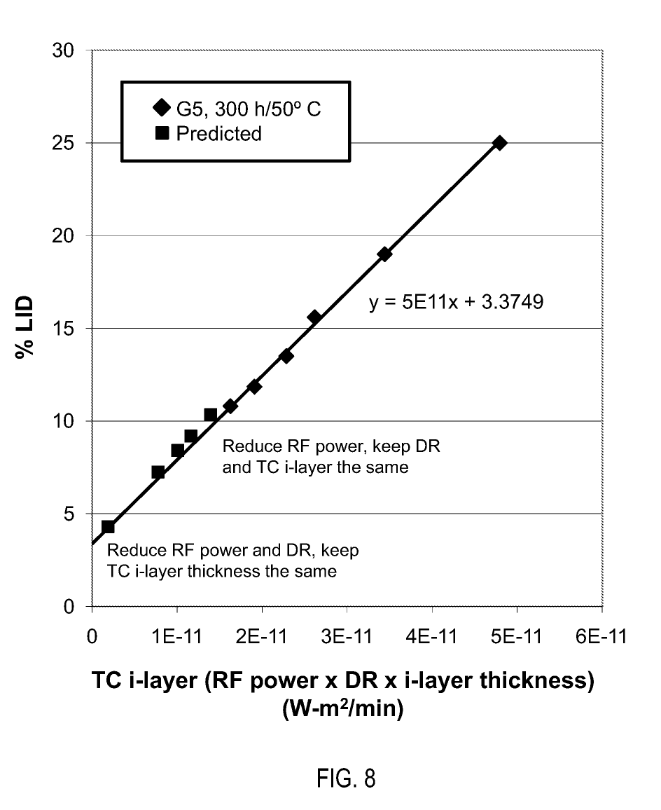

FIG. 8 illustrates a relationship between the percentage of light induced damage in a substrate deposited onto a wafer to a product of three parameters used during the processing of the wafer in accordance with an aspect of the present invention. The three parameters are the RF power in watts, the deposition rate in nanometers per min (nm/min) and the layer thickness of the deposited material in nanometers (nm).

As can be seen, the data points of the product of the three processing parameters form a linear relationship compared to light induced damage. As FIG. 8 makes clear, the operating points above about 12 percent light induced damage were obtained during operations. The points below about 12 percent light induced damage are predicted based on the linear relationship discovered in FIG. 8.

In accordance with one aspect of the present invention, the processing parameters of RF power, deposition rate and layer thickness are controlled by the controller 400 shown in FIG. 3 while depositing the intrinsic layer in the devices illustrated in FIGS. 1 and 2 in accordance with the relationship shown in FIG. 8 to achieve a desired light induced damage during processing. This can include the controller 400 controlling the RF power level introduced into the plasma generation region and the deposition rate of the intrinsic layer.

The controller 400 can also control the flow rate of gases introduced into the plasma generation region, such as the flow rate of silane. In one embodiment of the present invention a flow rate of less than 2250 sccm is used.

The controller 400 can also control the deposition temperature in the apparatus of FIG. 3. A temperature of greater than or equal to 230° C. can be used in one embodiment of the present invention. In one specific embodiment, a temperature of about 250° C. can be used.

The controller 400 can also control the ratio of hydrogen to silane that is introduced into the apparatus of FIG. 3 to influence the deposition rate. In one embodiment of the present invention, a ratio of H₂/SiH₄ of 6 or less is used. In another embodiment, a ratio of 4 or less is used.

In accordance with one aspect of the present invention, the apparatus of FIG. 3 is controlled to manufacturing an amorphous i-layer on a substrate with improved light induced damage is provided. The controller 400 controls the apparatus 300 to deposit, in a process chamber, the amorphous i-layer to a predetermined thickness by applying a gas mixture of H₂ and SiH₄ and a RF radiation at a power level to create a plasma. The power level of the RF radiation and a rate of deposition are selected by the controller 400 such that a product (x) of the power level in watts, the rate of deposition of the i-layer in nm per min and the thickness of the i-layer in nm is less than a predetermined number y and to satisfy the equation y=5E11*x+3.3749. The equation is derived from the results obtained in FIG. 8.

In accordance with one aspect of the invention, to allow for variances in processing tolerances, the equation is satisfied to a margin. For example, the equation can be satisfied to a margin of plus or minus 10% or less in accordance with one aspect of the present invention. In accordance with another aspect of the present invention, the equation can be satisfied to a tighter margin of plus or minus 5%.

In accordance with one aspect of the invention, y is selected to be 12. In this case, a percentage of light induced damage is approximately 12. In accordance with one aspect of the invention, y is selected to be less than 12. In this case, a percentage of light induced damage is also less than 12.

In accordance with another aspect of the present invention, the deposition temperature is greater than or equal to 230° C. In accordance with a further aspect of the present invention, the deposition temperature is approximately 250° C.

In accordance with another aspect of the present invention, wherein a ratio of H₂/SiH₄ used during processing is 6 or less. In accordance with a further aspect of the present invention, the ratio of H₂/SiH₄ used during processing is 4 or less.

In accordance with another aspect of the present invention, a flow rate of SiH₄ is less than 2250 sccm.

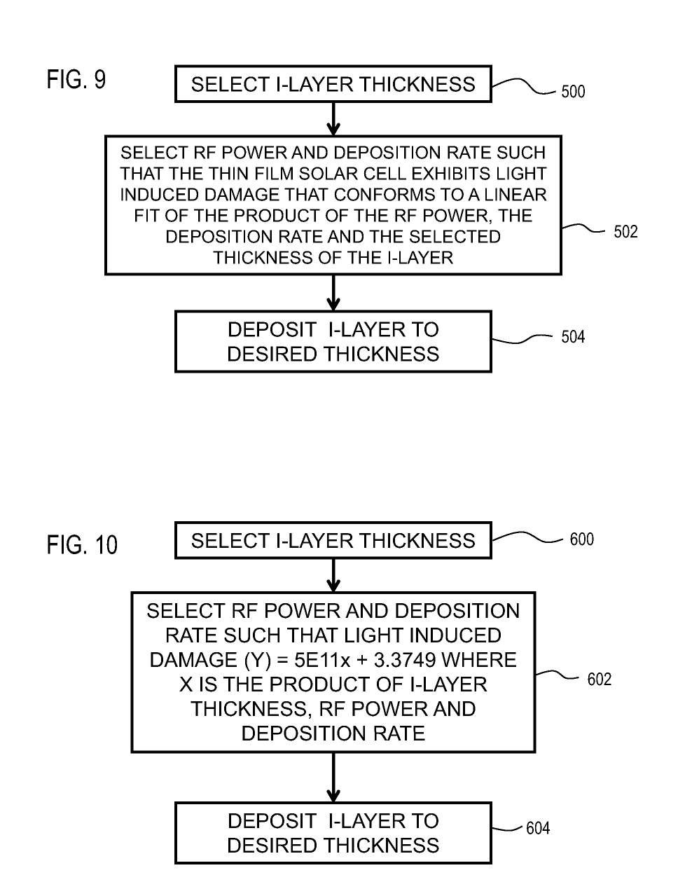

The steps used in accordance with one aspect of the present invention are shown in FIG. 9. In step 500, a desired thickness level of the intrinsic layer to be deposited is determined. In step 502, the controller 400 selects the RF power level to be applied in a plasma generations region to generate a plasma and thereby deposit a silicon-containing intrinsic layer at a deposition rate such that the thin film solar cell exhibits light induced damage that conforms to a linear fit of the product of the rf power, the deposition rate and the selected thickness of the i-layer. In step 504, the various gases, including hydrogen and silane are introduced to the plasma generation region in FIG. 3 and a selected RF power level is created in the plasma generation regions, all under the control of the controller 400 to achieve the linear fit of the product of the specified parameters.

FIG. 10 illustrates another method in accordance with an aspect of the present invention. The method includes the steps of selecting the intrinsic layer thickness in step 600 and then the controller 400 selecting the RF power level in the plasma generation region and the deposition rate such that the light induced damage (y) equals 5E11*x+3.3749, where x is the product of the intrinsic layer thickness, RF power and the deposition rate. The RF power is measured in watts, the deposition rate is measured in nanometers per minute and the thickness of the intrinsic layer is measured in nanometers. The light induced damage y is preferably selected to be less than a predetermined number and the above equation is satisfied by a margin. The margin is preferably plus or minus ten percent or less. In accordance with another embodiment, the margin is plus or minus five percent or less.

The light induced damage y is preferably selected to be 12 or less. It can also be selected to be 10 or less or 8 or less.

While there have been shown, described and pointed out fundamental novel features of the invention as applied to preferred embodiments thereof, it will be understood that various omissions and substitutions and changes in the form and details of the device illustrated and in its operation may be made by those skilled in the art without departing from the spirit of the invention. It is the intention, therefore, to be limited only as indicated by the scope of the claims appended hereto.

We claim:

1. An apparatus for forming a silicon-containing i-layer on a substrate for a thin film solar cell, comprising:
a chamber body defining a processing region containing the substrate;
a hydrogen source and a silane source coupled to a plasma generation region;
an RF power source that applies power at a power level in the plasma generation region to generate a plasma and deposit the silicon-containing i-layer at a selected deposition rate to a selected thickness;
a controller that controls the power level and the deposition rate of the i-layer on the substrate such that the thin film solar cell exhibits light induced damage that conforms to a linear fit of the product of the RF power, the deposition rate and the selected thickness of the i-layer.

2. The apparatus of claim 1, wherein the controller controls the RF power and the deposition rate so that the product (x) of the RF power in watts, the deposition rate of the i-layer in nm per min and the thickness of the i-layer in nm is less than a predetermined number y which is a measure of light induced damage and satisfies the equation y=5E11*x+3.3749 plus or minus a margin which is less than 10%.

3. The apparatus of claim 2, wherein the margin is less than 5%.

4. The apparatus of claim 2, wherein y is 12 or less.

5. The apparatus of claim 2, wherein y is 10 or less.

6. The apparatus of claim 2, wherein y is 8 or less.

7. The apparatus of claim 4, wherein the deposition temperature is greater than or equal to 230° C.

8. The apparatus of claim 4, wherein the deposition temperature is approximately 250° C.

9. The apparatus of claim 4, wherein a ratio of H₂/SiH₄ is 6 or less.

10. The apparatus of claim 4, wherein a ratio of H₂/SiH₄ is 4 or less.

11. The apparatus of claim 4, wherein a flow rate of SiH₄ is less than 2250 sccm.

12. A method of forming a thin film solar cell including an i-layer comprising in a processing chamber, comprising:
selecting a predetermined thickness of the i-layer to be formed on the substrate;
flowing silane and hydrogen gas into a plasma generation region of the chamber;
applying RF power at a selected power level to the plasma generation region to generate a plasma;
depositing the amorphous i-layer to the predetermined thickness at a deposition rate; and
controlling the deposition rate and RF power level such that the thin film solar cell exhibits light induced damage that conforms to a linear fit of the product of RF power, the deposition rate and the thickness of the i-layer.

13. The method of claim 1, further comprising controlling the RF power and the deposition rate so that a product (x) of the RF power in watts, the deposition rate of the i-layer in nm per min and the thickness of the i-layer in nm is less than a predetermined number y and satisfies the equation y=5E11*x+3.3749 plus or minus a margin which is less than 10%.

14. The method of claim 13, wherein the margin is less than 5%.

15. The method of claim 13, wherein y is 12 or less.

16. The method of claim 13, wherein y is 10 or less.

17. The method of claim 13, wherein y is 8 or less.

18. An apparatus for forming a silicon-containing i-layer on a substrate for a thin film solar cell, comprising:
a chamber body defining a processing region containing the substrate;
a hydrogen source and a silane source coupled to a plasma generation region;
an RF power source that applies power at a power level in the plasma generation region to generate a plasma;
a controller that controls the power level and a deposition rate of the i-layer on the substrate such that a product (x) of the power level in watts, the deposition rate of the i-layer in nm per min and the thickness of the i-layer in nm is less than a predetermined number y and satisfies the equation y=5E11*x+3.3749 plus or minus a margin which is less than 10%
wherein the silicon-containing i-layer is deposited on the substrate.

19. The apparatus of claim 18, wherein the margin is less than 5%.

20. The apparatus of claim 18, wherein y is 12 or less.
